(19) United States
(12) Patent Application Publication
(10) Pub. No.: US 2020/0258974 A1
(43) Pub. Date: Aug. 13, 2020

(54) DISPLAY DEVICE AND MANUFACTRUING METHOD THEREOF

(71) Applicant: WUHAN CHINA STAR OPTOELECTRONICS SEMICONDUCTOR DISPLAY TECHNOLOGYCO., LTD., Wuhan, Hubei (CN)

(72) Inventor: Weibin ZHANG, Wuhan, Hubei (CN)

(21) Appl. No.: 16/499,274

(22) PCT Filed: Feb. 21, 2019
(86) PCT No.: PCT/CN2019/075655

§ 371 Date: Sep. 29, 2019

(30) Foreign Application Priority Data
Dec. 10, 2018 (CN) 201811502179.5

(51) Int. Cl. H01L 27/32; H01L 51/00; H01L 51/56

(52) U.S. Cl. CPC H01L 27/3279; H01L 27/3248; H01L 27/3258; H01L 27/3262; H01L 2227/323; H01L 51/0097; H01L 51/56; H01L 2251/5338; H01L 27/3265

(57) ABSTRACT

A display device and a manufacturing method thereof are provided. The display device includes a bending area and a non-bending area. The non-bending area has an active area; and a first thin film transistor layer and a second thin film transistor layer disposed in the active area, wherein the second thin film transistor layer is disposed on the first thin film transistor layer. The peripheral circuit originally designed in the non-display area is changed to be disposed under the thin film transistor layer of the active area to avoid the non-active area of the screen occupied by the peripheral circuit, thereby increasing a screen ratio of the display device.

### FIELD OF INVENTION

The present invention relates to a display device and a manufacturing method thereof, and more particularly to a display device and a manufacturing method thereof for increasing a screen ratio.

### BACKGROUND OF INVENTION

In recent years, with the increasing use of display devices, development of display devices has trended to high screen ratios, and narrow bezels in the development of display devices. Regarding flexible display devices, current structures are generally provided by placing peripheral circuit structures (e.g., a plurality of thin film transistor structures) in a non-active area around the display device. However, such arrangement of the peripheral circuit structures will result in further increase in screen ratios of the display devices. Moreover, current flexible display devices generally adopt a bendable property of a flexible substrate disposed under a display panel, the flexible substrate is bent along a bending area to a back surface of the display panel, to increase a screen ratio of the display device. However, because the bending area of the flexible display device is also provided with some circuit structures (for example, a plurality of thin film transistor structures), It is also one of factors that limit the screen ratio to improve. In addition, the bending area may be provided with an inorganic layer to block permeation of moisture and oxygen to prevent from deterioration or failure of display elements and materials of the display device. However, the inorganic layer is prone to be broken after being bent a plurality of times or electric resistance increased due to deterioration of the material of the display elements. In addition, a plurality of thin film transistor structures are also prone to damage in the bending area.

Therefore, it is necessary to provide a display device and a manufacturing method thereof, to solve the problems in the conventional art.

### TECHNICAL PROBLEM

A problem exists in the conventional art that screen ratio cannot increase due to circuit structures generally disposed in a non-active area around a display device and a bending area under the display device, and other problems exist in the conventional art that an inorganic layer of the bending area is prone to be broken after the display device being bent a plurality of times, electric resistance is increased due to deterioration of the material of the display elements, and a plurality of thin film transistor structures are prone to damage.

### SUMMARY OF INVENTION

In view of above, the present invention provides a display device and a manufacturing method thereof, so as to solve the problem existing in the conventional art that the screen ratio cannot increase due to the circuit structures generally disposed in the non-active area around the display device and the bending area under the display device, and other problems exist in the conventional art that the inorganic layer of the bending area is prone to be broken after the display device being bent a plurality of times, the electric resistance is increased due to deterioration of the material of the display elements, and the thin film transistor structures are prone to damage.

A main object of the present invention is to provide a display device and a manufacturing method thereof, that can improve the screen ratio of the display device.

A secondary object of the present invention is to provide a display device and a manufacturing method thereof, that can dispose the circuit structures in an active area which are originally disposed in the non-active area around the display device and the bending area under the display device, so as to increase the screen ratio of the display device.

Another object of the present invention is to provide a display device and a manufacturing method thereof, that can prevent the problems that the inorganic layer of the bending area is prone to be broken after the display device being bent a plurality of times, the electric resistance is increased due to deterioration of the material of the display elements, and the thin film transistor structures are prone to damage to cause product failure.

In order to achieve the foregoing objects of the present invention, an embodiment of the present invention provides a display device, including: a substrate; a first buffer layer disposed on the substrate; a first thin film transistor layer disposed on the first buffer layer; a second buffer layer disposed on the first thin film transistor layer; a second thin film transistor layer disposed on the second buffer layer; a deep hole located between at least two of thin film transistors of the second thin film transistor layer, and passing through the first thin film transistor layer, the second buffer layer, and the second thin film transistor layer; and a planarization layer disposed on the second thin film transistor layer, and filled into the deep hole.

In an embodiment of the invention, the first thin film transistor layer includes a scan line circuit and an emission control line (EM) circuit.

In an embodiment of the invention, the first thin film transistor layer is a circuit with 10 TFT transistors and 3 storage capacitors (10T3C), or a circuit with 8 TFT transistors and 2 storage capacitors (8T2C).

In an embodiment of the invention, the second thin film transistor layer is an internal compensation type circuit.

In an embodiment of the invention, the second thin film transistor layer is a circuit with 7 TFT transistors and 1 storage capacitor (7T1C).

In an embodiment of the invention, the display device further includes: a via passing through the second buffer layer, the second thin film transistor layer, and the planarization layer; and an anode metal layer disposed on the planarization layer, wherein the first thin film transistor layer is connected to the anode metal layer through the via.

In an embodiment of the invention, the first thin film transistor layer and the second thin film transistor layer are arranged in a staggered manner.

Moreover, another embodiment of the present invention provides a display device, including: a bending area and a non-bending area, the non-bending area having an active area; and a first thin film transistor layer and a second thin film transistor layer both disposed in the active area, wherein the second thin film transistor layer is disposed on the first thin film transistor layer.

In an embodiment of the invention, the first thin film transistor layer includes a scan line circuit and an emission control line (EM) circuit.

In an embodiment of the invention, the second thin film transistor layer is an internal compensation type circuit.

In an embodiment of the invention, the second thin film transistor layer is a circuit with 7 TFT transistors and 1 storage capacitor (7T1C).

In an embodiment of the invention, the display device further includes: a substrate; a first buffer layer disposed on the substrate, the first thin film transistor layer disposed on the first buffer layer; a second buffer layer disposed on the first thin film transistor layer, the second thin film transistor layer disposed on the second buffer layer; and a planarization layer disposed on the second thin film transistor layer.

In an embodiment of the invention, the bending area has a deep hole passing through the first thin film transistor layer, the second buffer layer, and the second thin film transistor layer, wherein the planarization layer is filled into the deep holes.

In an embodiment of the invention, the display device further includes: a via passing through the second buffer layer, the second thin film transistor layer, and the planarization layer; and an anode metal layer disposed on the planarization layer, wherein the first thin film transistor layer is connected to the anode metal layer through the via.

In an embodiment of the invention, the first thin film transistor layer and the second thin film transistor layer are arranged in a staggered manner.

Furthermore, yet another embodiment of the present invention provides a manufacturing method of a display device, including steps of: providing a substrate; forming a first buffer layer on the substrate; forming a first thin film transistor layer on the first buffer layer; forming a second buffer layer on the first thin film transistor layer; forming a second thin film transistor layer on the second buffer layer; forming a deep hole between at least two of thin film transistors of the second thin film transistor layer, and passing through the first thin film transistor layer, the second buffer layer, and the second thin film transistor layer; and disposing a planarization layer on the second thin film transistor layer, and filling into the deep hole.

In an embodiment of the invention, the first thin film transistor layer includes a scan line circuit and an emission control line (EM) circuit.

In an embodiment of the invention, the second thin film transistor layer is an internal compensation type circuit.

In an embodiment of the invention, the second thin film transistor layer is a circuit with 7 TFT transistors and 1 storage capacitor (7T1C).

In an embodiment of the invention, the first thin film transistor layer and the second thin film transistor layer are arranged in a staggered manner.

### BENEFICIAL EFFECT

Compared with the conventional art, the display device and the manufacturing method thereof according to the present invention can increase the screen ratio of the display device by disposing the circuit structures in the active area which are originally disposed in the non-active area around the display device and the bend area under the display device. Furthermore, the display device and the manufacturing method thereof according to the present invention can solve problems existing in the conventional art that the inorganic layer of the bending area is prone to be broken after the display device being bent a plurality of times, the electric resistance is increased due to deterioration of the material of the display elements, and the thin film transistor structures are prone to damage by disposing the deep hole in the bending area of the display device and passing through the inorganic layer in the bending area of the display device.

### DRAWINGS

In order to make the above description of the present invention more comprehensible, the preferred embodiments are described below, and in conjunction with the accompanying drawings, the detailed description is as follows:

FIG. 1 is a schematic cross-sectional view of a display device according to an embodiment of the present invention.

### DETAILED DESCRIPTION OF EMBODIMENTS

The following description of the various embodiments is provided to illustrate the specific embodiments of the invention. Furthermore, the directional terms mentioned in the present invention, such as upper, lower, top, bottom, front, rear, left, right, inner, outer, side, surrounding, central, horizontal, horizontal, vertical, longitudinal, axial, radial, uppermost or lowermost, etc., only refer to the direction of the additional schema. Therefore, the directional terminology used is for the purpose of illustration and understanding of the invention.

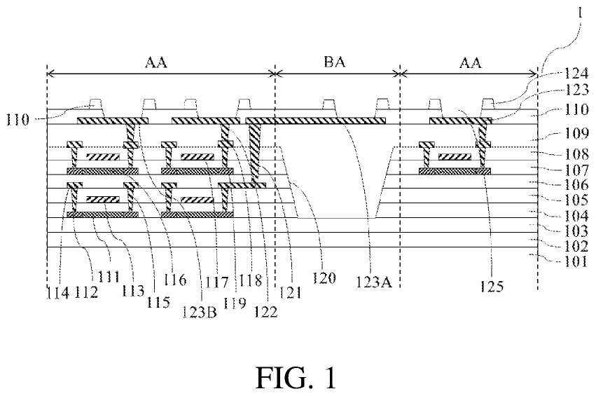

Referring to FIG. 1, in order to achieve the foregoing objects of the present invention, a display device 1 is provided. The display device 1 includes a first thin film transistor layer and a second thin film transistor layer, the second thin film transistor layer disposed on the first thin film transistor layer. Preferably, the first thin film transistor layer includes a scan line circuit and an emission control line (EM) circuit. The second thin film transistor layer is an internal compensation type circuit. Preferably, the second thin film transistor layer is an internal compensation type circuit. Optionally, the first thin film transistor layer is a 10T3C circuit or a 8T2C circuit, the 10T3C circuit is composed of 10 TFT transistors and 3 storage capacitors, and the 8T2C circuit is composed of 8 TFT transistors and 2 storage capacitors. Optionally, the second thin film transistor layer is a 7T1C circuit, the 7T1C circuit is composed of 7 TFT transistors and 1 storage capacitor. Optionally, the first thin film transistor layer has at least two groups of thin film transistors, a first group of thin film transistors is configured to sequentially turn on signals of scan gates in the first thin film transistor layer to complete pixel reset and data write to determine a gray scale of illumination. A second group of thin film transistors is configured to sequentially turn on the gate signals of the emission control line in the first thin film transistor layer to control whether a whole row of pixels illuminate or not.

Hereinafter, the detailed construction, assembly relationship, and operation principle of the above-described respective elements of the embodiments according to the present invention will be described in detail with reference to FIG. 1. The display device 1 includes a bending area BA and a non-bending area, and the non-bending area having an active area AA. A first thin film transistor layer and a second thin film transistor layer are disposed in the active area AA, and the second thin film transistor layer is disposed on the first thin film transistor layer. In addition, the display device 1 further includes a substrate 102, a first buffer layer 103, the first thin film transistor layer, a second buffer layer 106, the second thin film transistor layer, and a planarization layer 109. The substrate 102 may be a flexible substrate, such as a polyimide substrate. Optionally, a carrier 101, such as a glass substrate, may be disposed under the substrate 102. The first buffer layer 103 is disposed on the substrate 102. The first thin film transistor layer is disposed on the first buffer layer 103. Optionally, the first thin film transistor layer includes: a first active layer 111, a first gate insulating layer 104, a first gate 113, a second gate insulating layer 105, a first source/drain electrode 114, and a first source/drain via 115. The first active layer 111 is disposed on the first buffer layer 103, and the first active layer 111 has a first active layer doping area 112. The first gate insulating layer 104 is disposed on the first active layer 111 and covers the first active layer 111. The first gate 113 is disposed on the first gate insulating layer 104. The second gate insulating layer 105 is disposed on the first gate 113 and covers the first gate 113. The first source/drain electrode 114 is disposed on the second gate insulating layer 105 and connected to the first active layer 111 through the first source/drain via 115. The second buffer layer 106 is disposed on the first thin film transistor layer. The second thin film transistor layer is disposed on the second buffer layer 106. Optionally, the second thin film transistor layer includes: a second active layer 116, a third gate insulating layer 107, a second gate 1117, a fourth gate insulating layer 108, and a second source/drain electrode 118 and a second source/drain via 119. The second active layer 116 is disposed on the second buffer layer 106. The third gate insulating layer 107 is disposed on the second active layer 116 and covers the second active layer 116. The second gate 117 is disposed on the third gate insulating layer 107. The fourth gate insulating layer 108 is disposed on the second gate 117 and covers the second gate 117. The second source/drain electrode 118 is disposed on the fourth gate insulating layer 108 and connected to the second active layer 116 through the second source/drain via 119. The planarization layer 109 is disposed on the second thin film transistor layer. Optionally, the planarization layer 109 is disposed on the fourth gate insulating layer 108. Preferably, the bending area BA has a deep hole 120 passing through the first thin film transistor layer, the second buffer layer 106 and the second thin film transistor layer, and the planarization layer 109 fills in the deep hole 120. Optionally, the deep hole 120 further passes through the first gate insulating layer 104, the second gate insulating layer 105, the third gate insulating layer 107, and the fourth gate insulating layer 108. Optionally, a bottom of the deep hole 120 is flush with a bottom surface of the first gate insulating layer 104. In other words, the deep hole 120 only passes through to the first gate insulating layer 104 and exposes an upper surface of the first buffer layer 103. Optionally, the display device 1 further includes: a first via 121, a second via 122, and an anode metal layer 123. The first via 121 passes through the second buffer layer 106, the second thin film transistor layer, and the planarization layer 109. The anode metal layer 123 is disposed on the planarization layer 109, and the first thin film transistor layer is connected to a first anode 123A of the anode metal layer 123 through the first via 121. Optionally, the first via 121 further passes the third gate insulating layer 107 and the fourth gate insulating layer 108. The second via 122 passes through the planarization layer 109, and the second thin film transistor layer is connected to a second anode 123B of the anode metal layer 123 through the second via 122. Preferably, the display device 1 further includes: a pixel defining layer 110 and a photoresist spacer layer 124. The pixel defining layer 110 is disposed on the planarization layer 109. The pixel defining layer 110 has a plurality of openings 125 exposing the anode metal layer 123. The photoresist spacer layer 124 is disposed on the pixel defining layer 110 and disposed relative to the openings 125. Optionally, the second thin film transistor layer is directly disposed on the first thin film transistor layer. Alternatively, the first thin film transistor layer and the second thin film transistor layer are disposed in a staggered manner. Optionally, a thickness of the second buffer layer 106 is thicker than a thickness of the first buffer layer 103, to avoid mutual interference between the first thin film transistor layer and the second thin film transistor layer. Optionally, the second buffer layer 106 may further be provided with another organic layer to improve mutual interference between the first thin film transistor layer and the second thin film transistor layer. Optionally, the display device 1 has two active areas AA disposed on both sides of the bending area. One of the two active areas AA has the first thin film transistor layer and the second thin film transistor layer structures as described above, and the other of the two active areas AA is only provided with the second thin film transistor layer. Optionally, the carrier 101 may be removed or retained after the display device 1 is manufacturing completed.

Furthermore, another embodiment according to the present invention provides a manufacturing method of a display device 1, including steps of: providing a substrate 102; forming a first buffer layer 103 on the substrate; forming a first thin film transistor layer on the first buffer layer 103; forming a second buffer layer 106 on the first thin film transistor layer; forming a second thin film transistor layer on the second buffer layer 106; forming a deep hole 120 between at least two of thin film transistors of the second thin film transistor layer, and passing through the first thin film transistor layer, the second buffer layer 106, and the second thin film transistor layer; and disposing a planarization layer 109 on the second thin film transistor layer, and filling into the deep hole 120. The step of manufacturing method of forming the first thin film transistor layer further includes steps of: forming a first active layer 111 on the first buffer layer 103; forming a first active layer doping area 112 at the first active layer 111; forming a first gate insulating layer 104 on the first active layer 111 and covering the first active layer 111; forming a first gate 113 on the first gate insulating layer 104; forming a second gate insulating layer 10 on the first gate 113 and covering the first gate 113; forming a first source/drain electrode 114 on the second gate insulating layer 105; and forming a first source/drain via 115 to connect to the first active layer 111. The step of the manufacturing method of forming the second thin film transistor layer further includes steps of: forming a second active layer 116 on the second buffer layer 106; forming a third gate insulating layer 107 on the second active layer 116 and covering the second active layer 116; forming a second gate 117 on the third gate insulating layer 107; forming a fourth gate insulating layer 108 on the second gate 117 and covering the second gate 117; and forming a second source/drain electrode 118 on the fourth gate insulating layer 108, and connecting to the second active layer 116 through a second source/drain via 119. Optionally, the deep hole 120 is disposed at a bending area BA of the display device 1. The deep hole 120 passes through the first thin film transistor layer, the second buffer layer 106, and the second thin film transistor layer. The planarization layer 109 is filled into the deep hole 120. Optionally, the deep hole 120 further passes through the first gate insulating layer 104, the second gate insulating layer 105, the third gate insulating layer 107, and the fourth gate insulating layer 108. Optionally, the manufacturing method further includes step of: forming an anode metal layer 123 on the planarization layer 109. The first thin film transistor layer is connected to a first anode 123A of the anode metal layer 123 through a first via 121. Optionally, the first via 121 further passes through the third gate insulating layer 107 and the fourth gate insulating layer 108. The manufacturing method further includes the step of: forming a second via 122 passing through the planarization layer 109. The second thin film transistor layer is connected to a second anode 123B of the anode metal layer 123 through the second via 122. Preferably, the manufacturing method further includes steps of: forming a pixel defining layer 110 on the planarization layer 109, the pixel defining layer 110 having a plurality of openings 125 to expose the anode metal layer 123; and forming a photoresist spacer layer 124 on the pixel defining layer 110 and disposed relative to the openings 125.

As described above, compared with the problem existing in the conventional art that the screen ratio cannot increase due to the circuit structures generally disposed in the non-active area around the display device and the bending area under the display device, and other problems exist in the conventional art that the inorganic layer of the bending area is prone to be broken after the display device being bent a plurality of times, the electric resistance is increased due to deterioration of the material of the display elements, and the thin film transistor structures are prone to damage. The display device and the manufacturing method thereof according to the present invention can increase the screen ratio of the display device by disposing the circuit structures in the active area which are originally disposed in the non-active area around the display device and the bend area under the display device. Furthermore, the display device and the manufacturing method thereof according to the present invention can solve problems existing in the conventional art that the inorganic layer of the bending area is prone to be broken after the display device being bent a plurality of times, the electric resistance is increased due to deterioration of the material of the display elements, and the thin film transistor structures are prone to damage by disposing the deep hole in the bending area of the display device and passing through the inorganic layer in the bending area of the display device..

The present invention has been described by the above related embodiments, but the above embodiments are merely examples for implementing the present invention. It must be noted that the disclosed embodiments do not limit the scope of the invention. Rather, modifications and equivalent arrangements are intended to be included within the scope of the invention.

1. A display device, comprising:
a substrate;
a first buffer layer disposed on the substrate;
a first thin film transistor layer disposed on the first buffer layer;
a second buffer layer disposed on the first thin film transistor layer;
a second thin film transistor layer disposed on the second buffer layer;
a deep hole located between at least two of thin film transistors of the second thin film transistor layer, and passing through the first thin film transistor layer, the second buffer layer, and the second thin film transistor layer; and
a planarization layer disposed on the second thin film transistor layer, and filled into the deep hole.

2. The display device according to claim 1, wherein the first thin film transistor layer comprises a scan line circuit and an emission control line (EM) circuit.

3. The display device according to claim 1, wherein the first thin film transistor layer is a circuit with 10 TFT transistors and 3 storage capacitors, or a circuit with 8 TFT transistors and 2 storage capacitors.

4. The display device according to claim 1, wherein the second thin film transistor layer is an internal compensation type circuit.

5. The display device according to claim 4, wherein the second thin film transistor layer is a circuit with 7 TFT transistors and 1 storage capacitor.

6. The display device according to claim 1, the display device further comprising:
a via passing through the second buffer layer, the second thin film transistor layer, and the planarization layer; and
an anode metal layer disposed on the planarization layer,
wherein the first thin film transistor layer is connected to the anode metal layer through the via.

7. The display device according to claim 1, wherein the first thin film transistor layer and the second thin film transistor layer are arranged in a staggered manner.

8. A display device, comprising:
a bending area and a non-bending area, the non-bending area having an active area; and
a first thin film transistor layer and a second thin film transistor layer both disposed in the active area,
wherein the second thin film transistor layer is disposed on the first thin film transistor layer.

9. The display device according to claim 8, wherein the first thin film transistor layer comprises a scan line circuit and an emission control line (EM) circuit.

10. The display device according to claim 8, wherein the second thin film transistor layer is an internal compensation type circuit.

11. The display device according to claim 10, wherein the second thin film transistor layer is a circuit with 7 TFT transistors and 1 storage capacitor.

12. The display device according to claim 8, the display device further comprising:
a substrate;
a first buffer layer disposed on the substrate, the first thin film transistor layer disposed on the first buffer layer;
a second buffer layer disposed on the first thin film transistor layer, the second thin film transistor layer disposed on the second buffer layer; and
a planarization layer disposed on the second thin film transistor layer.

13. The display device according to claim 12, wherein the bending area has a deep hole passing through the first thin film transistor layer, the second buffer layer, and the second thin film transistor layer, wherein the planarization layer is filled into the deep holes.

14. The display device according to claim 12, the display device further comprising:
a via passing through the second buffer layer, the second thin film transistor layer, and the planarization layer; and
an anode metal layer disposed on the planarization layer,
wherein the first thin film transistor layer is connected to the anode metal layer through the via.

15. The display device according to claim 8, wherein the first thin film transistor layer and the second thin film transistor layer are arranged in a staggered manner.

16. A manufacturing method of a display device, comprising steps of:
providing a substrate;
forming a first buffer layer on the substrate;
forming a first thin film transistor layer on the first buffer layer;
forming a second buffer layer on the first thin film transistor layer;
forming a second thin film transistor layer on the second buffer layer;
forming a deep hole between at least two of thin film transistors of the second thin film transistor layer, and passing through the first thin film transistor layer, the second buffer layer, and the second thin film transistor layer; and
disposing a planarization layer on the second thin film transistor layer, and filling into the deep hole.

17. The manufacturing method of the display device according to claim 16, wherein the first thin film transistor layer comprises a scan line circuit and an emission control line (EM) circuit.

18. The manufacturing method of the display device according to claim 16, wherein the second thin film transistor layer is an internal compensation type circuit.

19. The manufacturing method of the display device according to claim 18, wherein the second thin film transistor layer is a circuit with 7 TFT transistors and 1 storage capacitor.

20. The manufacturing method of the display device according to claim 16, wherein the first thin film transistor layer and the second thin film transistor layer are arranged in a staggered manner.
